(19) United States
(12) Patent Application Publication
(10) Pub. No.: US 2007/0236227 A1
(43) Pub. Date: Oct. 11, 2007

(54) WAVEFORM CONVERTING APPARATUS, WAVEFORM CONVERTING METHOD TEST APPARATUS AND TEST METHOD

(75) Inventor: Koji Asami, Tokyo (JP)

Correspondence Address: ROBERT E. LOCKMAN, JR., 256 STATE ROAD 292 EAST, TUNKHANNOCK, PA, 18657, US

(73) Assignee: ADVANTEST CORPORATION, TOKYO (JP)

(21) Appl. No.: 11/735,509

(22) Filed: Apr. 16, 2007

Related U.S. Application Data
(63) Continuation of application No. PCT/JP05/18870, filed on Oct. 13, 2005.

(30) Foreign Application Priority Data
Oct. 19, 2004 (JP) 2004-304936

(51) Int. Cl. G01R 31/08

(52) U.S. Cl. 324/521

(57) ABSTRACT

An waveform converting apparatus is provided. The waveform converting apparatus includes: an amplitude converting section that multiplies an amplitude component of the input signal more than a predetermined amplitude value by a conversion coefficient which gradually decreases in accordance with the amplitude value; and a filter that removes a frequency component out of the frequency band of the input signal among the frequency components of the signal generated by the amplitude converting section.

### CROSS REFERENCE TO RELATED APPLICATION

This is a continuation application of PCT/JP2005/018870 filed on Oct. 13, 2005 which claims priority from a Japanese Patent Application NO. 2004-304936 filed on Oct. 19, 2004, the contents of which are incorporated herein by reference.

### BACKGROUND

1. Technical Field

The present invention relates to an waveform converting apparatus and an waveform converting method that remove amplitude component more than a predetermined reference value of the provided input signal, and a test apparatus that tests a communication amplifier. Particularly, the present invention relates to an waveform converting apparatus that removes a large amplitude component without generating any distortion of the out-of-band component of an input signal.

2. Related Art

A communication amplifier used for a mobile communication and a wireless LAN may have been evaluated by using an input signal of which amplitude is limited in accordance with the function of the communication amplifier. Generally, the amplitude of the input signal has been limited by clipping.

FIG. 8 is an explanatory diagram showing the limitation of the amplitude of an input signal by clipping.

FIG. 8A shows an input signal before clipping and an input signal after clipping.

As shown in FIG. 8A, the general clipping replaces the amplitude value of the amplitude component more than a predetermined reference value v1 with the reference value in order to limit the amplitude.

FIG. 8B shows the spectrum of an input signal before clipping and the spectrum of an input signal after clipping.

When the above described limitation of the amplitude, there is change little or nothing in the in-band component of the input signal but the out-of-band component such as a higher harmonic appears.

If the communication amplifier is evaluated by using the input signal with the out-of-band component, it is difficult to evaluate any distortion of the in-band component due to the communication amplifier.

In addition, when a filtering is performed in order to remove the out-of-band component of the input signal after clipping, the input signal after the filtering could be got back to the input signal before clipping.

Thus, it has been difficult for the conventional method for limiting the amplitude to satisfy both of limiting the amplitude of the input signal and preventing the any distortion of the out-of-band component of the input signal from generating.

FIG. 8C shows ccdf (Complementary Cumulative Distribution Function) characteristic of the input signal before clipping and ccdf of the input signal after clipping. Since the amplitude is limited in ccdf of the input signal after clipping, ccdf for the amplitude of the input signal more than the predetermined reference value v1 is 0 as shown in the solid line of the right graph of FIG. 8C. However, the ccdf of the input signal which is filtered in order to remove the out-of-band component thereof after clipping is not 0 when the input signal has the amplitude component more than the predetermined reference value v1 as shown in the dotted line of the right graph of FIG. 8C, therefore, the amplitude of the input signal can not be limited.

When the communication amplifier is evaluated, it is desired that the characteristic of all the component of the in-band input signal is evaluated. Therefore, it is desired that the input signal used to evaluate the communication amplifier has a wide spectrum in the band thereof. However, since the spectrum of the input signal in the band is changed little or nothing in the conventional method for limiting the band, the spectrum of the input signal still has a sharp peak at a predetermined frequency in the band.

Here, any related patent document is not currently found, so that the description is omitted.

### SUMMARY

As described above, it is difficult for the conventional method for limiting a band to limit the amplitude of an input signal without generating any distortion of the out-of-band component of the input signal. In addition, it is difficult to generate an input signal of which amplitude is limited and which has a wide spectrum in the band.

Thus, the object of the present invention is to provide an waveform converting apparatus, an waveform converting method and a test apparatus which are capable of solving the problem accompanying the conventional art. The above and other objects can be achieved by combining the features recited in independent claims. Then, dependent claims define further effective specific example of the present invention.

In order to solve the above described problems, a first aspect of the present invention provides an waveform converting apparatus that removes the amplitude component of a provided input signal more than a predetermined reference value. The waveform converting apparatus includes: an amplitude converting section that multiplies an amplitude component of the input signal more than a predetermined amplitude value by a conversion coefficient which is defined in accordance with the amplitude value; and a filter that removes a frequency component out of the frequency band of the input signal among the frequency components of the signal generated by the amplitude converting section.

The amplitude converting section may store the predetermined amplitude value less than the predetermined reference value. The amplitude converting section may store the conversion coefficient which is 1 for the amplitude component less than the predetermined amplitude value of the input signal and which is gradually decreased in accordance with the amplitude value for the amplitude component more than the predetermined amplitude value of the input signal.

The amplitude converting section may store the conversion coefficient of which derivatives are continued. The amplitude converting section may include: an energy calculating section that calculates an energy of a clipping signal obtained by clipping the input signal by the predetermined reference value and an energy of a converted signal obtained by multiplying the amplitude component of the input signal more than the predetermined reference value by the conversion coefficient which is gradually decreased in accordance with the amplitude value; an amplitude value calculating section that calculates a predetermined amplitude value based on the ratio between the energy of the clipping signal and the energy of the converted signal and stores the same; and a conversion coefficient calculating section that generates a conversion coefficient based on the predetermined amplitude value and stores the same. The conversion coefficient calculating section may generate the conversion coefficient for the amplitude component more than the predetermined amplitude value based on a cosine function having the half-period from the predetermined amplitude value to the maximum value of the amplitude of the input signal.

A second aspect of the present invention provides an waveform converting method that removes the amplitude component of the provided input signal more than a predetermined reference value. The waveform converting method includes the step of: multiplying an amplitude component of the input signal more than a predetermined amplitude value by a conversion coefficient which is defined in accordance with the amplitude value; and removing a frequency component out of the frequency band of the input signal among the frequency components of the signal generated by the amplitude converting step. The conversion coefficient may gradually decrease in accordance with the amplitude value.

The amplitude converting step may store the predetermined amplitude value less than the predetermined reference value. The amplitude converting step may store the conversion coefficient which is 1 for the amplitude component of the input signal less than the predetermined amplitude value and which gradually decreases in accordance with the amplitude value for the amplitude component of the input signal more than the predetermined amplitude value.

The amplitude converting step may store the conversion coefficient of which derivatives are continued. The amplitude converting step may include: calculating the energy of a clipping signal obtained by clipping the input signal by the predetermined reference value and the energy of a converted signal obtained by multiplying an amplitude component of the input signal equal to or more than the reference value by the conversion coefficient which gradually decreases in accordance with the amplitude value; calculating the predetermined amplitude value based on the ratio between the energy of the clipping signal and the energy of the converted signal and storing the same, and generating the conversion coefficient based on the predetermined amplitude value and storing the same. The conversion coefficient calculating step may generate the conversion coefficient for the amplitude component equal to or more than the predetermined amplitude value based on a cosine function having the half-period from the predetermined amplitude value to the maximum value of the amplitude of the input signal.

A third aspect of the present invention provides a test apparatus that tests a communication amplifier. The test apparatus includes: an waveform generating section that generates an input signal for testing the communication amplifier; an waveform converting apparatus that removes the amplitude component of the input signal more than a predetermined reference value and provides the same to the communication amplifier; and a judgment section that judges pass/fail of the communication amplifier based on an output signal outputted from the communication amplifier. The waveform converting apparatus includes an amplitude converting section that multiplies an amplitude component of the input signal more than a predetermined amplitude value by a conversion coefficient which is defined in accordance with the amplitude value; and a filter that removes a frequency component out of the frequency band of the input signal among the frequency components of the signal generated by the amplitude converting section. The conversion coefficient may gradually decrease in accordance with the amplitude value.

A fourth aspect of the present invention provides a method for testing a communication amplifier. The method includes the steps of: generating an input signal for testing the communication amplifier; removing the amplitude component of the input signal more than a predetermined reference value and providing the same to the communication amplifier; and judging pass/fail of the communication amplifier based on an output signal outputted from the communication amplifier. The waveform converting step including: multiplying an amplitude component of the input signal more than a predetermined amplitude value by a conversion coefficient which is defined in accordance with the amplitude value; and removing a frequency component out of the frequency band of the input signal among the frequency components of the signal generated by the amplitude converting section.. The conversion coefficient may gradually decrease in accordance with the conversion coefficient.

Here, all necessary features of the present invention are not listed in the summary of the invention. The sub-combinations of the features may become the invention.

### BRIEF DESCRIPTION OF THE DRAWINGS

FIG. 1 shows an example of configuration of a test apparatus 100 according to an embodiment of the present invention;

FIG. 2 shows an example of conversion coefficient stored in an waveform converting apparatus 20;

FIG. 3 shows an example of configuration of the waveform converting apparatus 20;

FIG. 4 shows examples of waveform of an input signal: FIG. 4A shows an example of waveform of the input signal generated by an waveform generating section 10; and FIG. 4B shows an example of waveform of the input signal outputted by the waveform converting section 30;

FIG. 5 shows examples of spectrum of the input signal: FIG. 5A shows an example of spectrum of the input signal generated by the waveform generating section 10; and FIG. 5B shows an example of spectrum of the input signal outputted by the waveform converting apparatus 20;

FIG. 6 shows an example of ccdf characteristic of the input signal outputted by the waveform converting apparatus 20;

FIG. 7 shows an example of waveform converting method according to an embodiment of the present invention; and

FIG. 8 is an explanatory diagram showing the conventional limitation of the amplitude of the input signal by clipping: FIG. 8A shows an input signal before clipping and an input signal after clipping; FIG. 8B shows the spectrum of the input signal before clipping and the spectrum of the input signal after clipping; and FIG. 8C shows ccdf of the input signal before clipping and ccdf of the input signal after clipping.

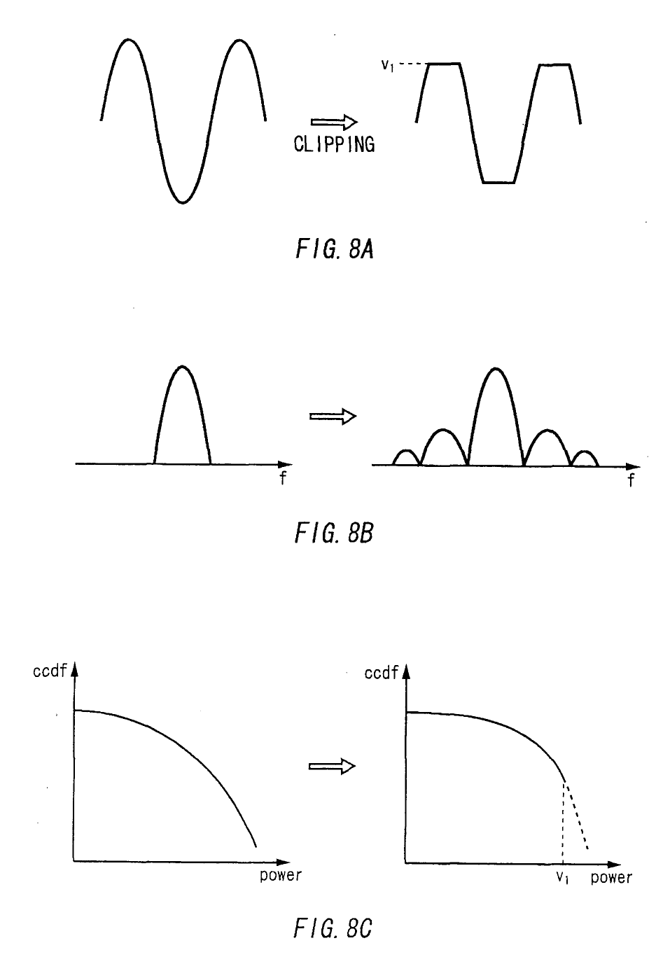

### DESCRIPTION OF EXEMPLARY EMBODIMENTS

Hereinafter, the present invention will now be described through preferred embodiments. The embodiments do not limit the invention according to claims and all combinations of the features described in the embodiments are not necessarily essential to means for solving the problems of the invention.

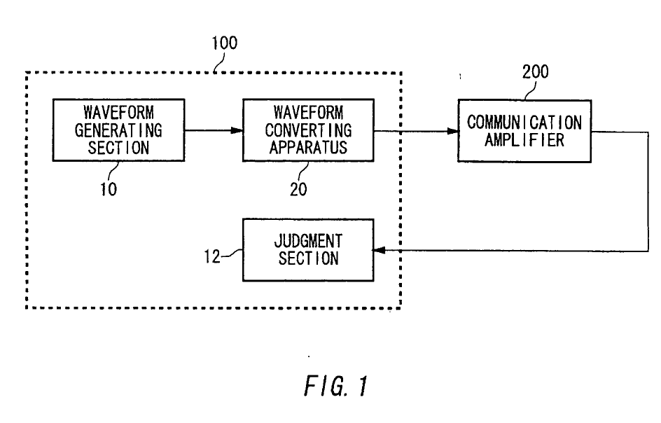

FIG. 1 shows an example of configuration of a test apparatus 100 according to an embodiment of the present invention. The test apparatus 100 tests a communication amplifier 200 used for such as radio communication and has an waveform generating section 10, an waveform converting apparatus 20 and a judgment section 12.

The waveform generating section 10 generates an input signal for testing the communication amplifier 200. The waveform generating section 10 generates an input signal having the frequency component in the frequency band appropriate for evaluating the characteristic of the communication amplifier. For example, the waveform generating section 10 generates the input signal substantially equal to a carrier wave inputted when the communication amplifier 20 is actually used.

The waveform converting apparatus 20 removes the amplitude component, of the input signal generated by the waveform generating section, more than a predetermined reference value and provides the same to the communication amplifier 200. Here, the predetermined reference value may be any numerical value previously provided from the user of the test apparatus 100. The waveform converting apparatus 20 limits the amplitude of the input signal by multiplying each amplitude component of the input signal generated by the waveform generating section 10 by a conversion coefficient in accordance with the value of the amplitude component in the present embodiment. The waveform converting apparatus 20 may store a prepared conversion coefficient. In addition, a reference value appropriate for limiting the amplitude of the input signal to be inputted to the communication amplifier 200 may be previously provided to the waveform converting apparatus 20, and the waveform converting apparatus 20 may generate the conversion coefficient based on the reference value and store the same.

The judgment section 12 judges pass/fail of the communication amplifier based on the output signal outputted by the communication amplifier 200. For example, the judgment section 200 compares the spectrum of the signal inputted from the waveform converting apparatus 20 to the communication amplifier 200 with the spectrum of the output signal to judge pass/fail of the communication amplifier.

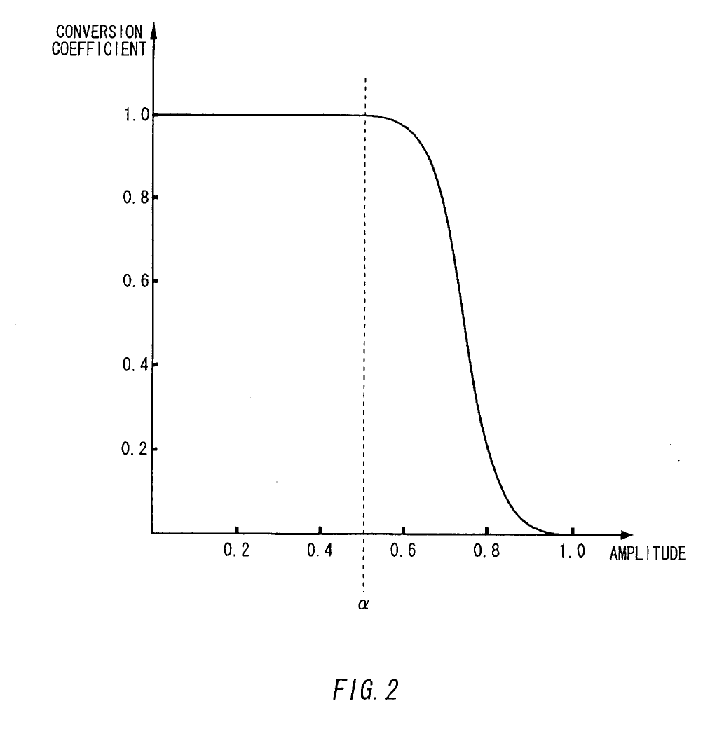

FIG. 2 shows an example of conversion coefficient stored in an waveform converting apparatus 20. The horizontal axis shows the amplitude values of an input signal and the vertical axis shows the conversion coefficient for each of the amplitude values in FIG. 2. In addition, the amplitude value of the input signal indicates the ratio to the maximum amplitude of the input signal in FIG. 2.

The waveform converting apparatus 20 stores the conversion coefficient for each amplitude component more than the predetermined amplitude value α of the input signal, which is gradually decreases in accordance with the amplitude value as shown in FIG. 2. That is, the waveform converting apparatus 20 stores 1 as the conversion coefficient in a region in which the amplitude value of the input signal is less than α, and stores the conversion coefficient equal to or less than 1 which gradually decreases in accordance with the amplitude value in a region in which the amplitude value of the input signal is equal to or more than α.

In addition, the waveform converting apparatus 20 may store any conversion coefficient provided that the value multiplied by the conversion coefficient corresponding to each amplitude value of the input signal is not more than the predetermined reference value described above. By using such conversion coefficient, the amplitude of the input signal can be limited to equal to or less than the predetermined reference value.

Moreover, it is preferred that the waveform converting apparatus 20 stores the conversion coefficient of which derivatives obtained by differentiating the conversion coefficient as a function of the amplitude of the input signal by the amplitude are continued. Thus, the amplitude of the input signal is converted by using the conversion coefficient, so that any out-of-band component of the input signal after converting the amplitude can be reduced.

The waveform converting apparatus 20 according to the present embodiment stores the conversion coefficient as a cosine function for the amplitude component more than α which has the half-period from the amplitude value α to the maximum value of the amplitude.

For example, the waveform converting apparatus 20 stores the conversion coefficient f(v) indicated by the following expression.

$$f ( v ) = \{ \begin{matrix}1 , & v < α \\ 0.5 \times \{ cos ( π \frac{v - α}{1 - α} ) + 1.0 \} , & v \geq α\end{matrix} \qquad Expression 1$$

Where, v indicates the amplitude of the input signal.

In addition, it is preferred that the waveform converting apparatus 20 removes the frequency component out of the frequency band of the input signal generated by the waveform generating section 10 among the frequency components of the input signal after converting the amplitude.

Thereby the communication amplifier 200 can be accurately evaluated.

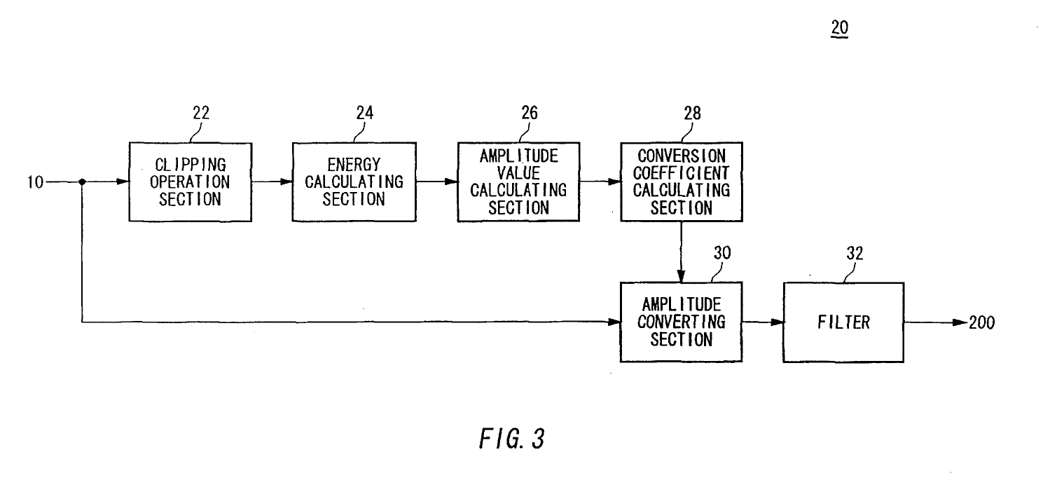

FIG. 3 shows an example of configuration of the waveform converting apparatus 20. The waveform converting apparatus 20 according to the present embodiment is provided with a predetermined reference value to limit the amplitude of the input signal as described above, generates the conversion coefficient described with reference to FIG. 2 and stores the same. The waveform converting apparatus 20 includes a clipping operation section 22, an energy calculating section 24, an amplitude value calculating section 26, a conversion coefficient calculating section 28, an amplitude converting section 30 and a filter 32.

The clipping operation section 22 generates a clipping signal obtained by clipping a provided input signal by the reference value. In addition, the clipping operation section 22 generates a converted signal obtained by converting the amplitude of the input signal by using the above-described predetermined amplitude value as the reference value as described in FIG. 2. For example, when the reference value is v1, the clipping operation section 22 generates a converted signal by amplifying each amplitude of the input signal by the conversion coefficient indicated by the following expression.

$$f ( v ) = \{ \begin{matrix}1 , & v < {v}_{1} \\ 0.5 \times \{ cos ( π \frac{v - {v}_{1}}{1 - {v}_{1}} ) + 1.0 \} , & v \geq {v}_{1}\end{matrix}$$

Then, the energy calculating section 24 calculates the energy for each of the clipping signal and the converted signal.

The amplitude value calculating section 26 calculates a predetermined amplitude value α based on the ratio between the energy of the clipping signal and the energy of the converted signal and stores the same. For example, the amplitude value calculating section 26 calculates the amplitude value α based on the following expression.

$$α = {v}_{1} - ( 1 - {v}_{1} ) \times \frac{hcpwr}{scpwr} \times \frac{cf \times {v}_{1}^{2}}{v max} \qquad Expression 2$$

where, hcpwr indicates the energy of the clipping signal, scpwr indicates the energy of the converted signal, cf is the crest factor (amplitude/effective value) of the clipping signal and vmax indicates the maximum value of the amplitude of the input signal.

Then, the conversion coefficient calculating section 28 generates the conversion coefficient described with reference to FIG. 2 based on the amplitude value α calculated by the amplitude value calculating section 26 and stores the same. For example, the conversion coefficient calculating section 28 may generate the conversion coefficient based on the expression 1.

The amplitude converting section 30 converts the amplitude of the input signal generated by the waveform generating section 10 based on the conversion coefficient stored in the conversion coefficient calculating section 28. The filter 32 removes the component out of the band of the input signal of which amplitude has been converted by the amplitude converting section 30 and provides the same to the communication amplifier 200. By such operation, the amplitude of the input signal can be limited without generating any distortion of the out-of-band component of the input signal.

In addition, the input signal having a wide spectrum can be generated in the frequency band appropriate for evaluating the characteristic of the communication amplifier 200.

In addition, when the frequency characteristic of the input signal inputted to the filter 32 is not in proportion to the carrier wave of the input signal, the filter 32 may filter after shifting the frequency characteristic of the input signal. For example, when the frequency band of the input signal is in −50 MHz-150 Mhz and the frequency of the carrier wave is at 0 MHz, the filter 32 shifts the frequency characteristic of the input signal by −50 MHz to filter the same. In addition, the filter 32 shifts the frequency characteristic after filtering by 50 MHz. The passing band of the filter 32 is symmetrically set to the frequency of the carrier wave, so that the frequency characteristic of the input signal can be symmetrically filtered by the above-described processing.

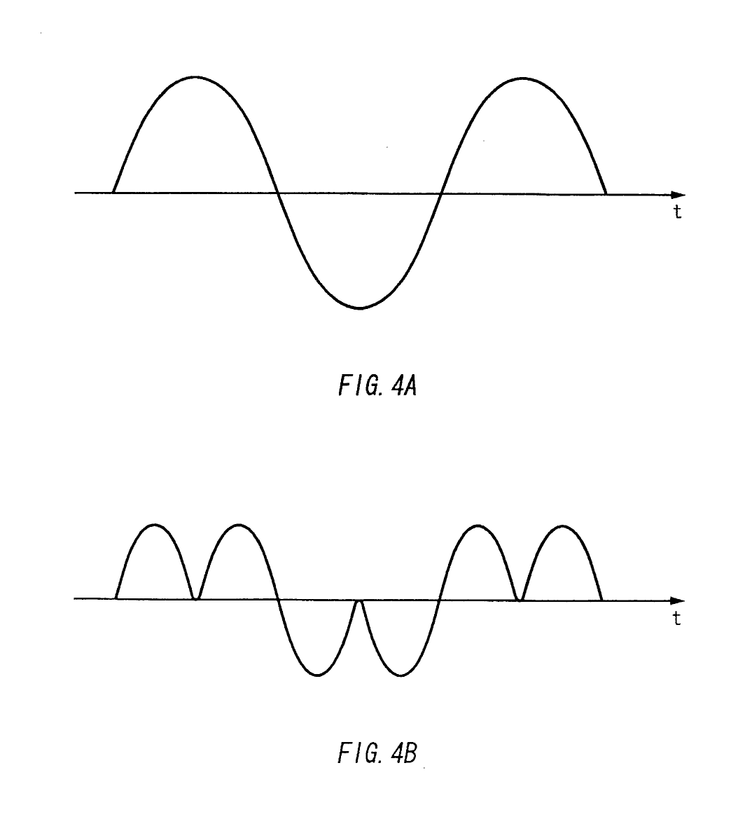

FIG. 4 shows examples of waveform of an input signal: FIG. 4A shows an example of waveform of the input signal generated by an waveform generating section 10; and FIG. 4B shows an example of waveform of the input signal outputted by the waveform converting apparatus 20.

As shown in FIG. 2, the conversion coefficient is 1 in a region in which the amplitude value of the input signal is less than α, and is gradually decreased in accordance with the amplitude value in a region in which the amplitude value of the input signal is equal to or more than cc and then is 0 at the maximum amplitude of the input signal. Therefore, the input signal of which amplitude is converted has the amplitude 0 at the phase of the maximum amplitude thereof before converting the amplitude as shown in FIG. 4B.

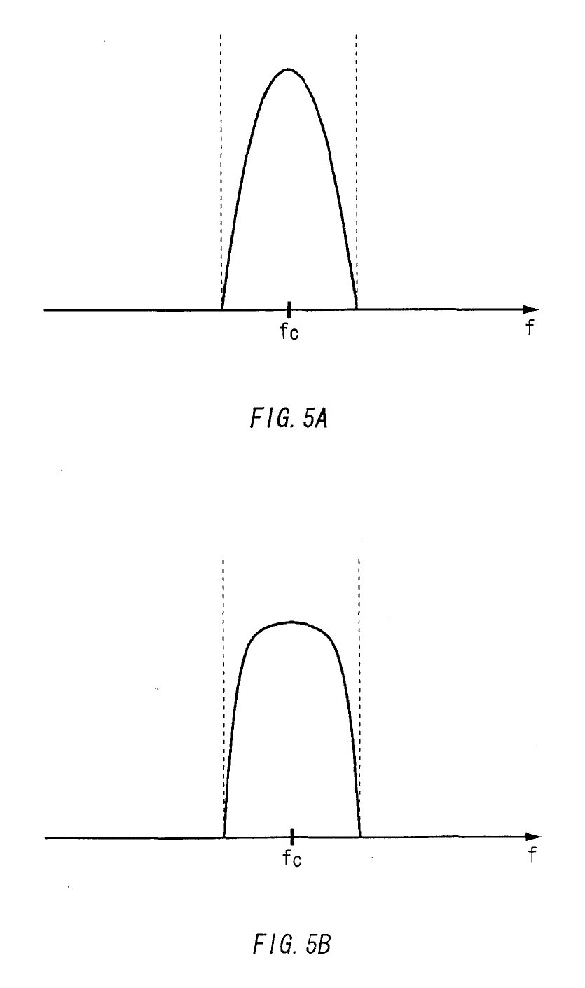

FIG. 5 shows examples of spectrum of the input signal: FIG. 5A shows an example of spectrum of the input signal generated by the waveform generating section 10; and FIG. 5B shows an example of spectrum of the input signal outputted by the waveform converting apparatus 20.

By performing the amplitude conversion described above, the input signal has a wide spectrum within the band as show in FIG. 3B.

In addition, the out-of-band frequency component of the input signal can be removed by being passed through the filter 32.

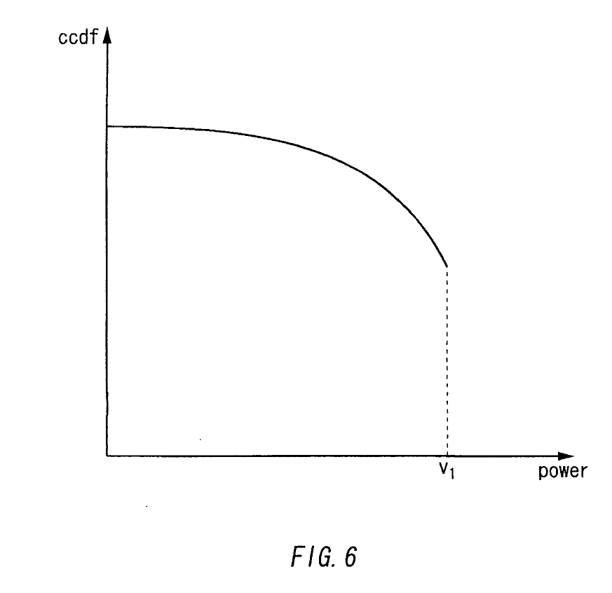

FIG. 6 shows an example of ccdf of the input signal outputted by the waveform converting apparatus 20. The waveform converting apparatus 20 according to the present embodiment limits the amplitude by gradually decreasing the conversion coefficient by which the amplitude of the input signal generated by the waveform generating section 10 is multiplied from the amplitude value α less than the predetermined value v1 appropriate for limiting the amplitude of the input signal inputted to the communication amplifier 200. The maximum amplitude of the input signal after passing through the filter 32 can be limited to v1 by setting the amplitude value α to an appropriate value. In addition, the amplitude value of the input signal after converting the amplitude is smoothly changed as shown in FIG. 4B. Therefore, the distortion of the out-of-band component of the input signal can be reduced and the spectrum within the band of the input signal can be distorted by such limitation of the amplitude.

In addition, when the maximum amplitude value of the input signal outputted by the filter 32 is not corresponding to the predetermined reference value v1, the waveform converting apparatus 20 may adjust the amplitude value a and match the amplitude value of the input signal with the predetermined reference value v1.

By such processing, the maximum amplitude of the input signal can be accurately matched with the predetermined reference value v1 as shown in FIG. 6.

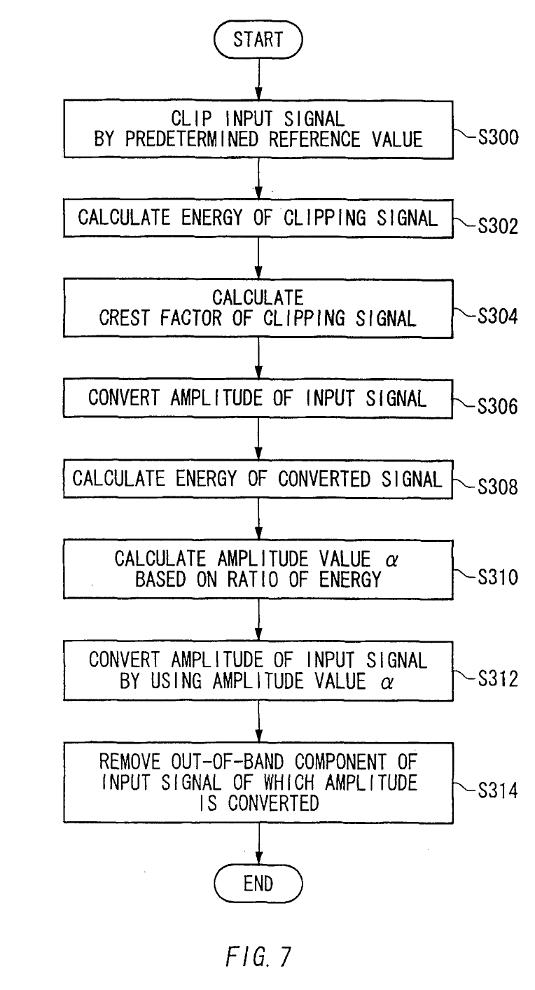

FIG. 7 shows an example of waveform converting method according to an embodiment of the present invention. The waveform converting method limits the amplitude of a provided input signal by the process the same as that of the waveform converting apparatus 20 described above with reference to FIG. 1-FIG. 6.

Firstly, a clipping signal obtained by clipping the provided input signal by the predetermined reference value v1 is generated in a clipping step S300.

Next, the energy of the clipping signal is calculated in an energy calculating step S302. Then, the crest factor of the clipping signal is calculated.

Next, a converted signal obtained by converting the amplitude of the provided signal is generated (S306). In the amplitude conversion in the S306, the amplitude of the input signal is converted as described in FIG. 2 by using the above described predetermined amplitude value as the predetermined reference value v1.

Then, the energy of the converted signal is calculated (S308).

Next, the amplitude value a is calculated based on the ratio between the energy of the clipping signal and the energy of the converted signal (S310). The amplitude value α is calculated by using such as the expression 2 in S310. Then, the amplitude of the input signal is converted by using the amplitude value α in the amplitude converting step S312. The amplitude of the input signal is converted by using such as the expression 1 in the S312.

Next, the out-of-band component of the input signal of which amplitude has been converted is removed in the filtering step 314. By limiting the amplitude of the input signal through such processing, an input signal having the desired ccdf can be easily generated.

Moreover if the maximum amplitude value of the input signal generated in the filtering step S314 is not corresponding to the predetermined reference value v1, the processing from the S312 to the S314 may be repeated with adjusting the amplitude value α. For example, when the maximum amplitude value of the input signal is more than the reference value v1, the amplitude value α is reduced, alternatively when the maximum amplitude value of the input signal is less than the reference value v1, the amplitude value α is increased.

While the present invention has been described with the embodiment, the technical scope of the invention not limited to the above described embodiment. It is apparent to persons skilled in the art that various alternations and improvements can be added to the above-described embodiment. It is apparent from the scope of the claims that the embodiment added such alternation or improvements can be included in the technical scope of the invention.

As evidenced by the above description, according to the present invention, the amplitude of the input signal can be limited without generating any distortion of the out-of-band component of the input signal.

Moreover, the input signal having a wide spectrum within the band can be generated.

What is claimed is:

1. An waveform converting apparatus that removes an amplitude component of a provided input signal more than a predetermined reference value, comprising:
an amplitude converting section that multiplies an amplitude component of the input signal more than a predetermined amplitude value by a conversion coefficient which is defined in accordance with the amplitude value; and
a filter that removes a frequency component out of the frequency band of the input signal among the frequency components of the signal generated by the amplitude converting section.

2. The waveform converting apparatus as set forth in claim 1, wherein the conversion coefficient gradually decreases in accordance with the amplitude value.

3. The waveform converting apparatus as set forth in claim 2, wherein the amplitude converting section stores the predetermined amplitude value less than the predetermined reference value.

4. The waveform converting apparatus as set forth in claim 3, wherein the amplitude converting section stores the conversion coefficient which is 1 for the amplitude component of the input signal less than the predetermined amplitude value and which is gradually decreases in accordance with the amplitude value for the amplitude component of the input signal more than the predetermined amplitude value.

5. The waveform converting apparatus as set forth in claim 4, wherein the amplitude converting section stores the conversion coefficient of which derivatives are continued.

6. The waveform converting apparatus as set forth in claim 5, wherein the amplitude converting section including:
an energy calculating section that calculates the energy of a clipping signal obtained by clipping the input signal by the predetermined reference value and the energy of a converted signal obtained by multiplying an amplitude component of the input signal equal to or more than the reference value by the conversion coefficient which gradually decreases in accordance with the amplitude value;
an amplitude value calculating section that calculates the predetermined amplitude value based on the ratio between the energy of the clipping signal and the energy of the converted signal and stores the same, and
a conversion coefficient calculating section that generates the conversion coefficient based on the predetermined amplitude value and stores the same.

7. The waveform converting apparatus as set forth in claim 6, wherein the conversion coefficient calculating section generates the conversion coefficient for the amplitude component equal to or more than the predetermined amplitude value based on a cosine function having the half-period from the predetermined amplitude value to the maximum value of the amplitude of the input signal.

8. An waveform converting method for removing an amplitude component of a provided input signal more than a predetermined reference value, comprising:
multiplying an amplitude component of the input signal equal to or more than a predetermined amplitude value by a conversion coefficient which is defined in accordance with an amplitude value; and
removing a frequency component out of the frequency band of the input signal among the frequency components of the signal generated by the amplitude converting step.

9. The waveform converting method as set forth in claim 8, wherein the conversion coefficient gradually decreases in accordance with the amplitude value.

10. The waveform converting method as set forth in claim 9, wherein the amplitude converting step stores the predetermined amplitude value less than the predetermined reference value.

11. The waveform converting method as set forth in claim 10, wherein the amplitude converting step stores the conversion coefficient which is 1 for the amplitude component of the input signal less than the predetermined amplitude value and which gradually decreases in accordance with the amplitude value for the amplitude component of the input signal more than the predetermined amplitude value.

12. The waveform converting method as set forth in claim 11, wherein the amplitude converting step stores the conversion coefficient of which derivatives are continued.

13. The waveform converting method as set forth in claim 12, wherein the amplitude converting step including:
calculating the energy of a clipping signal obtained by clipping the input signal by the predetermined reference value and the energy of a converted signal obtained by multiplying an amplitude component of the input signal equal to or more than the reference value by the conversion coefficient which gradually decreases in accordance with the amplitude value;
calculating the predetermined amplitude value based on the ratio between the energy of the clipping signal and the energy of the converted signal and storing the same, and
generating the conversion coefficient based on the predetermined amplitude value and storing the same.

14. The waveform converting method as set forth in claim 13, wherein the conversion coefficient calculating step generates the conversion coefficient for the amplitude component equal to or more than the predetermined amplitude value based on a cosine function having the half-period from the predetermined amplitude value to the maximum value of the amplitude of the input signal.

15. A test apparatus that tests a communication amplifier, comprising:
an waveform generating section that generates an input signal for testing the communication amplifier;
an waveform converting apparatus that removes the amplitude component of the input signal more than a predetermined reference value and provides the same to the communication amplifier; and
a judgment section that judges pass/fail of the communication amplifier based on an output signal outputted from the communication amplifier,
the waveform converting apparatus including:
an amplitude converting section that multiplies an amplitude component of the input signal more than a predetermined amplitude value by a conversion coefficient which is defined in accordance with the amplitude value; and
a filter that removes a frequency component out of the frequency band of the input signal among the frequency components of the signal generated by the amplitude converting section.

16. The waveform converting apparatus as set forth in claim 15, wherein the conversion coefficient gradually decreases in accordance with the amplitude value.

17. A method for testing a communication amplifier, comprising:
generating an input signal for testing the communication amplifier;
removing the amplitude component of the input signal more than a predetermined reference value and providing the same to the communication amplifier; and
judging pass/fail of the communication amplifier based on an output signal outputted from the communication amplifier,
the waveform converting step including:
multiplying an amplitude component of the input signal more than a predetermined amplitude value by a conversion coefficient which is defined in accordance with the amplitude value; and
removing a frequency component out of the frequency band of the input signal among the frequency components of the signal generated by the amplitude converting section.

18. The waveform converting apparatus as set forth in claim 17, wherein the conversion coefficient gradually decreases in accordance with the amplitude value.
